(19) United States
(12) Patent Application Publication
(10) Pub. No.: US 2025/0058555 A1
(43) Pub. Date: Feb. 20, 2025

(54) METHOD OF FABRICATING A NANOSTRUCTURE LAYER STACK

(71) Applicant: RAMOT AT TEL-AVIV UNIVERSITY LTD., Tel Aviv (IL)

(72) Inventors: Tal ELLENBOGEN, Tel Aviv (IL); Tsafrir ABIR, Tel Aviv (IL); Sharon KAREPOV, Tel Aviv (IL); Danielle BEN HAIM, Tel Aviv (IL)

(21) Appl. No.: 18/721,229

(22) PCT Filed: Dec. 19, 2022
(86) PCT No.: PCT/IL2022/051348

§ 371 Date: Jun. 18, 2024

Related U.S. Application Data
(60) Provisional application No. 63/291,483, filed on Dec. 20, 2021.

(51) Int. Cl. B32B 37/02; B32B 7/12; B32B 37/12

(52) U.S. Cl. CPC B32B 37/02; B32B 7/12; B32B 37/12

(57) ABSTRACT

A method for producing a nanostructure layer stack having a plurality of N nanostructure layers adhered together, the method comprising: fabricating at least one nanostructure layer of N nanostructure layers comprised in a nanostructure stack on a substrate that is not another of the N nanostructure layers: vetting the at least one nanostructure layer to determine if the at least one nanostructure layer satisfies a quality constraint; and if the at least one nanostructure layer satisfies the quality constraint, adhered each of the at least one nanostructure layer to another nanostructure layer of the N nanostructure layers to form the nanostructure stack.

### FIELD

Embodiments of the disclosure relate to methods of integrating a plurality of layers each comprising a pattern of nanometer features into a 3D stack that facilitates cooperation of the layers to support a desired application.

### BACKGROUND

Various nanofabrication technologies for manufacturing substantially 2D patterns of features on a substrate that exhibit high lateral spatial resolution of less than hundreds of nanometers have been developed and are in use in various nanofabrication processes, no less of which are the various fabrication processes used in the production of integrated circuits and nanophotonic devices. However, the use of these technologies to produce devices that comprise a plurality of layers, each layer having a high spatial resolution pattern of functional structures so that the structures in the different layers cooperate to provide a desired function has proven to be relatively complex, expensive, and as a result, of limited scalability.

For example, for nanophotonic applications the expanded design possibilities provided by 3D multilayer stacks of nonlinear metasurfaces (NLMs), each layer having a surface array of subwavelength antennas, may be particularly advantageous for producing nonlinear frequency conversion devices configured for different applications such as: high resolution infrared imaging; spectroscopy; tomography; communications; biomedicine, security; and molecular scale probing and manipulating of materials. Relatively inexpensive, scalable methods for producing multilayer stacks of metasurfaces tailored to different features of these applications may facilitate adoption of nonlinear frequency conversion for use in the applications and research into discovering and engineering new applications of frequency conversion. Quite generally, inexpensive, scalable methods for nanostructure multi-stacking may enable advantageous adoption of various nanofabrication technologies such as nanoprinting and nanoelectronics to new and previously impractical applications.

For convenience of presentation a relatively thin substrate comprising a pattern of features exhibiting relatively high lateral spatial resolution of less than hundreds of nanometers in or on a surface of the substrate may be referred to as a nanostructure layer, and when understood from the context as referring to a nanostructure layer, simply a layer.

### SUMMARY

An aspect of an embodiment of the disclosure relates to providing a method of producing a nanostructure layer stack also referred to as a “nanostructure stack” comprising a plurality of N nanostructure layers, for which at least one given layer of the N layers is not fabricated on another of the layers in the stack but is aligned with and placed on another layer of the stack after fabrication of the given layer.

In an embodiment, optionally none of the layers in a metasurface stack are fabricated on another of the layers in the stack. As a result, an operating cost exclusive of tooling for producing a nanostructure stack in accordance with an embodiment increases substantially linearly with a number N of layers in the stack.

On the other hand in prior art, nanostructure layers in a nanostructure stack are fabricated one on the other to provide the stack. As a result during fabrication of the stack, if fabrication of a given layer fails, and the given layer is determined to be faulty, at least all the previously fabricated nanostructure layers in the stack are generally determined to be unusable and contribute to a production loss. As a result, the operating cost of producing a nanostructure stack increases exponentially with a number N of layers in the stack.

A fabrication method, hereinafter also referred to as an Advanced Nanostructure Stacking (ANSTACK) method, or simply ANSTACK, for producing a nanostructure stack in accordance with an embodiment of the disclosure provides rapidly increasing savings as the number of nanostructure layers in the stack increases.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF FIGURES

Non-limiting examples of embodiments of the invention are described below with reference to figures attached hereto that are listed following this paragraph. Identical features that appear in more than one figure are generally labeled with a same label in all the figures in which they appear. A label labeling an icon representing a given feature of an embodiment of the invention in a figure may be used to reference the given feature. Dimensions of features shown in the figures are chosen for convenience and clarity of presentation and are not necessarily shown to scale.

FIG. 1A schematically illustrates production of a nanostructure stack in accordance with prior art;

FIG. 1B shows a graph of yield and cost curves as functions of a number N of nanostructure layers in a nanostructure stack for the prior art production method shown in FIG. 1A;

FIG. 2A schematically illustrates production of a nanostructure stack in accordance with and embodiment of the disclosure; and

FIG. 2B shows a graph of yield and cost curves as functions of a number N of nanostructure layers in a nanostructure stack produced in accordance with an embodiment of the disclosure.

### DETAILED DESCRIPTION

In the discussion, unless otherwise stated, adjectives such as “substantially” and “about” modifying a condition or relationship characteristic of a feature or features of an embodiment of the disclosure, are understood to mean that the condition or characteristic is defined to within tolerances that are acceptable for operation of the embodiment for an application for which it is intended. Wherever a general term in the disclosure is illustrated by reference to an example instance or a list of example instances, the instance or instances referred to, are by way of non-limiting example instances of the general term, and the general term is not intended to be limited to the specific example instance or instances referred to. Unless otherwise indicated, the word “or” in the description and claims is considered to be the inclusive “or” rather than the exclusive or, and indicates at least one of, or any combination of more than one of items it conjoins.

As noted above, in an embodiment, optionally none, of the layers in a metasurface stack are fabricated on another of the layers in the stack and an operating cost C(N), inclusive of setup costs, for producing a nanostructure stack in accordance with an embodiment increases substantially linearly with a number N of layers in the stack. Let a fabrication yield for a single nanostructure layer in a stack is represented by FY₁, and a corresponding cost of production be represented by FC₁. Then the operating cost, C(N), for producing a nanostructure stack comprising N nanostructure layers in accordance with an embodiment may therefore be modeled by an expression:

$$C ( N ) = α N \cdot {FC}_{1} + γ \qquad ( 1 )$$

where α is a constant of proportionality and γ is a set up cost for preparing a production run.

In prior art, nanostructure layers in a nanostructure stack are fabricated one on the other to provide the stack and if fabrication of a given layer fails, the given layer and generally at least all the previously fabricated nanostructure layers in the stack are “lost”. If Cₚ(N) represents an operating cost of producing a nanostructure stack containing N nanostructure layers in accordance with prior art fabrication methods, Cₚ(N) may therefore be modeled by an expression,

$${C}_{p} ( N ) = β ( {FC}_{1} + γ ) \cdot 〈 M 〉 / {FY}_{N} . \qquad ( 2 )$$

In expression (2), β is a constant of proportionality, [symbol] M [symbol] is an average number of nanostructure layers fabricated before a fabrication failure, and FY_{N} is a fabrication yield for producing a nanostructure stack comprising N nanostructure layers. For prior art fabrication generally each nanostructure layer imposes the setup γ on Cₚ(N) and therefore γ adds to the cost FC₁ of each layer and multiplies [symbol] M [symbol] as shown in expression (2). FY_{N} is equal to a probability of fabricating an uninterrupted sequence of N “good” nanostructure layers and may be written,

$${FY}_{N} = {FY}_{1}^{N} . \qquad ( 3 )$$

Using (3), expression (2) may be rewritten,

$${C}_{p} ( N ) = β ( {FC}_{1} + γ ) \cdot 〈 M 〉 / {FY}_{1}^{N} . \qquad ( 4 )$$

A cost ratio CR(N)=Cₚ(N)/C(N) for producing an N layer nanostructure stack in accordance with prior art relative to a cost for producing the same stack in accordance with an embodiment of the disclosure may therefore be indicated by an expression,

$$CR ( N ) = {C}_{p} ( N ) / C ( N ) = β ( {FC}_{1} + γ ) \cdot 〈 M 〉 / ( ( {FY}_{1}^{N} ) ( α N \cdot {FC}_{1} + γ ) ) \qquad ( 5 )$$

Expression (5) indicates that with increasing N the cost of producing a nanostructure stack relative to that of the cost in accordance with an embodiment of the disclosure may be expected to grow substantially exponentially.

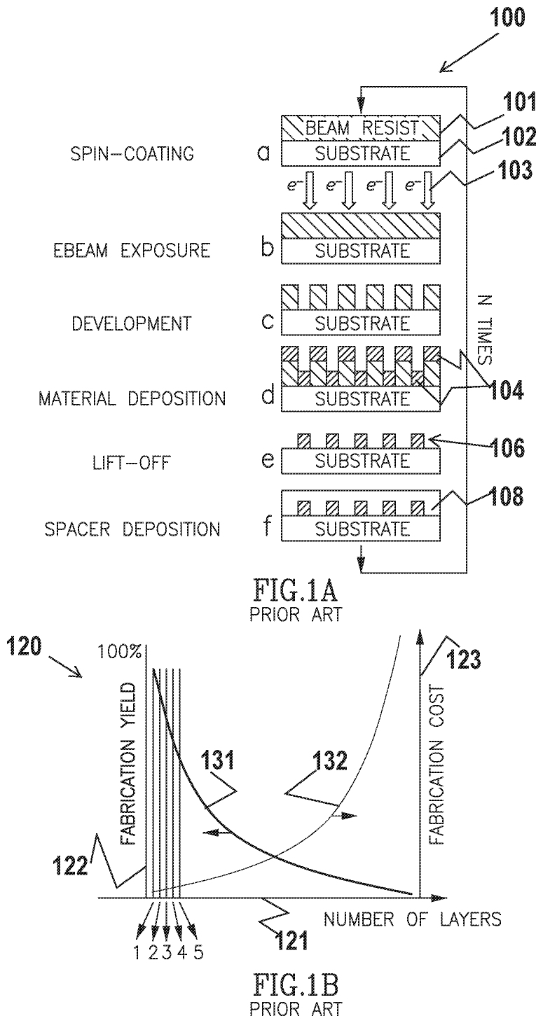

FIG. 1A schematically shows a visual flow diagram of a prior art fabrication method 100 for producing a nanostructure stack using, by way of example, electron-beam lithography (EBL).

In a panel, a, a beam resist 101 is applied to a substrate 102, and in a panel, b, an electron beam 103 exposes the resist to a desired pattern of nanostructure features to be formed on the substrate. In a panel, c, resist 101 is developed to wash away the regions of the resist that were exposed to the electron beam. After development of resist 101, in a panel, d, a desired material 104 is deposited on the substrate. Subsequently in a panel, e, the desired material deposited on resist 101 remaining on the substrate is lifted off the substrate to produce and leave a nanostructure pattern 106 of desired material, as shown in panel e. In a panel, f, a protective spacer 108 is formed on nanostructure pattern 106 to protect the pattern and complete production of a first nanostructure layer 110 of the stack and provide a finished a surface on which to fabricate a next nanostructure pattern of features. The actions illustrated in panels a-f are repeated (N−1) times to form each newly fabricated nanostructure layer of the nanostructure stack on protective spacer 108 of the preceding nanostructure layer and build a nanostructure stack of N layers.

For the prior art fabrication process illustrated in FIG. 1A a graph 120 in FIG. 1B shows a curve 131 of a nanostructure stack fabrication yield in accordance with expression (3) as a function of a number N of layers in the stack for an arbitrary value for FY₁ that is less than 1. Values provided by curve 131 for yield FY_{N} as a function of N indicated along the graph abscissa 121 are shown along an arbitrary scale lefthand ordinate 122 of the graph. Production costs, FC_{N}, for the prior art nanostructure stack as a function of the number of layers are given by a curve 132. Values for the production costs provided by curve 132 are indicated along an arbitrary scale, righthand ordinate 123 of graph 120. As shown in the graph, the yield decreases and the corresponding cost increases substantially exponentially with N.

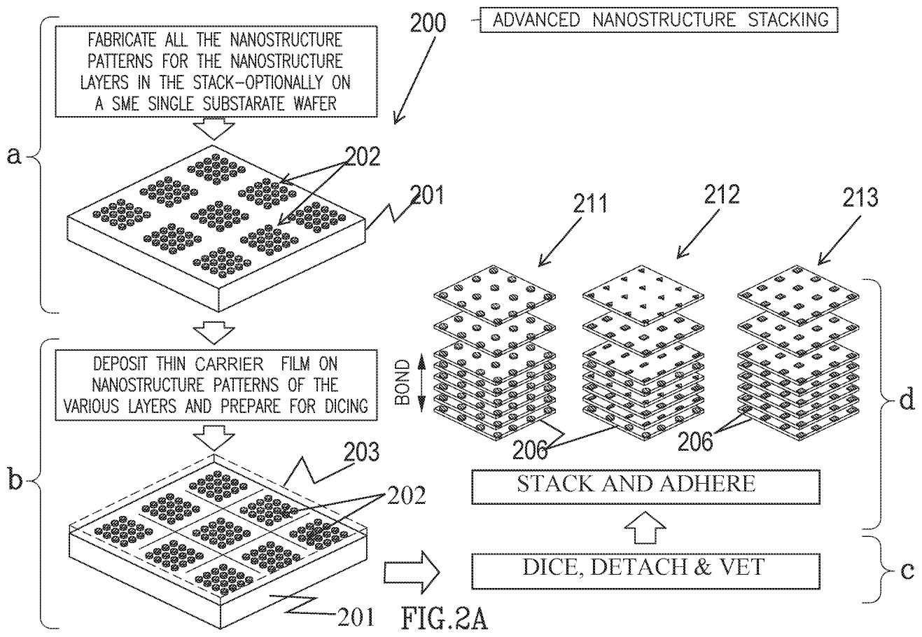

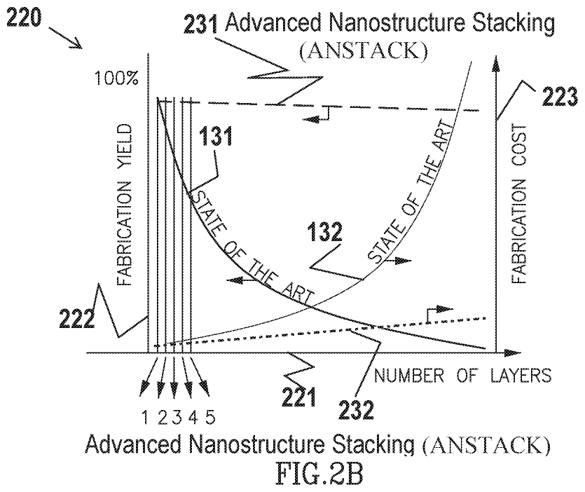

FIG. 2A shows a schematic, visual flow diagram of an Advanced Nanostructure Stacking, ANSTACK, method 200 used to produce at least one nanostructure stack, in accordance with an embodiment of the disclosure.

In a panel, a, at least one and optionally all of the different nanostructure patterns 202 of at least one nanostructure stack are fabricated on a substrate wafer 201, and in a panel, b, a protective “carrier film” 203 that sticks to nanostructure patterns 202 is formed to cover the fabricated patterns. Optionally, features of different nanostructure patterns 202 and/or features in a same nanostructure pattern 202 may be formed from different materials. Thickness of carrier film 203 may be determined so that portions, hereinafter also referred to as “pellicles 203”, of the layer associated with each pattern 202 functions as a spacer between arrays of nanostructure patterns 202 in the final at least one nanostructure stack produced by ANSTACK. In a panel, c, the formed patterns, optionally together with substrate 201, are diced to separate tiles, each tile comprising one of nanostructure patterns 202 and its pellicle 203. The patterns 202 and their respective pellicles are detached from substrate 201 to form an individual nanostructure layer 206 to be vetted to determine if it satisfies quality constraints and if satisfying the constraints to be stacked to form the at least one nanostructure stack. It is noted that whereas panel c indicates that vetting quality is done after dicing, in an embodiment of the disclosure vetting quality may be performed prior to dicing while nanostructure patterns 202, with or without carrier layer 203, are residing on substrate 201. In a panel, d, nanostructure layers 206 that meet the quality constraints are stacked and adhered together to produce optionally three different nanostructure stacks 211, 212, and 213, in accordance with an embodiment. Adhering a nanostructure layer to another nanostructure layer may be effected by any of various methods that operate to firmly hold a first nanostructure layer to a second nanostructure layer so as to moderate against their relative displacement. Adhering may by way of example be effected by bonding, gluing, adhesive bonding, ultrasonic welding, or generating advantageous electrostatic or contact friction forces between layers. Adhering does not include fabricating a nanostructure layer on another nanostructure layer in a nanostructure stack.

In an embodiment, after a given nanostructure layer 206 is adhered to another nanostructure layer 206 in the process of forming a nanostructure stack in accordance with an embodiment of the disclosure, pellicle 203 of the given layer may be removed to enable a next nanostructure layer in the stack to be adhered directly to the nanostructure pattern 202 of the given layer. Optionally, the next nanostructure layer is adhered to the nanostructure pattern 202 of the given layer with the nanostructure pattern 202 of the next nanostructure layer facing the nanostructure pattern 202 of the given layer. As a result two nanostructure patterns may face each other with substantially no intervening pellicle.

In an embodiment removal of a pellicle 203 between nanostructure layers 206 may be performed after the nanostructure stack or a portion thereof is formed by immersing the stack or portion thereof in a liquid that dissolves the pellicle. Dissolution of the pellicle may be facilitated by vibrating the stack or portion thereof with vibrations that are perpendicular to the nanostructure layers in the stack. In an embodiment pellicle 203 may be removed prior to adhering and substrate 201 relied upon to maintain structural integrity of the nanostructure pattern 202 during stacking and adhering.

In an embodiment nanostructure layers may be lifted, moved, aligned and positioned one on another in the stack using an ANSTACK pick and place robot (not shown), optionally referred to as a Robo-Stacker. Optionally, the Robo-Stacker comprises a high resolution touch gripper configured to hold a nanostructure layer 206 using by way of example forces generated by electrostatic or magnetic fields, a vacuum and/or by temperature controlled adhesion.

Whereas in the above description of process 200 nanostructure layers are described as being fabricated on a same wafer that is relatively large with respect to the individual nanostructure layers, practice of an embodiment of the disclosure is not limited to fabricating all the optionally different nanostructure layers comprised in a nanostructure stack on a same, or on one substrate wafer. For example, only one type of each of the nanostructured layers to be comprised in a given nanostructure stack may be fabricated on a same wafer, and to produce the given nanostructure stack different nanostructure layers from different wafers may be stacked and adhered together to produce the stack. And, optionally, each nanostructure layer may be fabricated on its own dedicated substrate.

A graph 220 in FIG. 2B shows a curve 231 of yield FY_{N} as a function of a number N of layers in the stack for a nanostructure stack fabricated in accordance with ANSTACK 200 illustrated in FIG. 2A. Values provided by curve 231 for the yield FY_{N} indicated along the graph abscissa 221 are shown along an lefthand, arbitrary scale ordinate 222 of the graph. Production costs, FC_{N}, corresponding to FY_{N} given by curve 231 for the nanostructure stack as a function of the number of layers are given by a curve 232. Values for the production costs provided by curve 232 are indicated along a righthand, arbitrary scale ordinate 223 of graph 220. As shown in the graph, the yield decreases moderately and linearly with N and the cost increases moderately and linearly with N. For convenience of comparison, curves 131 and 132 shown in FIG. 1B for fabrication yields and production costs for the same nanostructure stacks produced by prior art methods are reproduced in FIG. 2B.

Descriptions of embodiments of the invention in the present application are provided by way of example and are not intended to limit the scope of the invention. The described embodiments comprise different features, not all of which are required in all embodiments. Some embodiments utilize only some of the features or possible combinations of the features. Variations of embodiments of the invention that are described, and embodiments comprising different combinations of features noted in the described embodiments, will occur to persons of the art. The scope of the invention is limited only by the claims.

1. A method for producing a nanostructure stack having a plurality of N nanostructure layers adhered together, the method comprising:
fabricating a given nanostructure layer of the N nanostructure layers on a substrate that is not another of the N nanostructure layers, each of the N nanostructure layers having a respective pattern of nanostructure features; and
adhering the given nanostructure layer to another nanostructure layer of the N nanostructure layers to produce the nanostructure stack;
wherein fabricating the given nanostructure layer comprises fabricating the respective pattern of nanostructure features for a plurality of the given nanostructure layers on the same substrate.

2. (canceled)

3. The method according to claim 1 wherein fabricating the given nanostructure layer comprises fabricating the respective pattern of nanostructure features for each of a plurality of the N nanostructure layers in the nanostructure stack on the same substrate.

4. The method according to claim 3 wherein the plurality of the N nanostructure layers comprises all the N nanostructure layers in the nanostructure stack.

5. The method according to claim 3 wherein the plurality of the N nanostructure layers comprises nanostructure layers having different patterns of nanostructure features.

6. The method according to claim 5 wherein the different patterns of nanostructure features comprise different nanostructure features.

7. The method according to claim 5 wherein the different patterns of nanostructure features comprise nanostructure features made from different materials.

8. The method according to claim 5 wherein the different patterns of nanostructure features comprise a same nanostructure feature in different orientations.

9. The method according to claim 1 and comprising forming a carrier film over the nanostructure feature patterns fabricated on the same substrate.

10. The method according to claim 9 and comprising removing the carrier film.

11. The method according to claim 10 wherein removing the carrier film comprises removing before adhering.

12. The method according to claim 10 wherein removing the carrier film comprises removing after adhering.

13. The method according to claim 12 wherein removing the carrier film after adhering comprises immersing the adhered nanostructure layers in a solution that dissolves the carrier film.

14. The method according to claim 13 wherein removing the carrier film comprises vibrating the adhered nanostructure layers.

15. The method according to claim 1 and comprising dicing the plurality of the N nanostructure patterns fabricated on the same substrate.

16. The method according to claim 1 wherein adhering the given nanostructure layer to the another nanostructure layer comprises adhering the nanostructure layers so that the nanostructure patterns of features in the layers face each other.

17. The method according to claim 1 and comprising vetting quality of the given nanostructure layer to determine if the given nanostructure layer satisfies a quality constraint and adhering the given nanostructure layer to another nanostructure layer in the nanolayer stack only if the vetting of the given nanostructure layer indicates that the given nanostructure layer satisfies the quality constraint.

18. (canceled)

19. The method according to claim 1 wherein adhering comprises using a pick and place machine to position and place and the given nanostructure layer to the another nanostructure layer.

20. The method according to claim 1 wherein the nanostructure features of the given layer are characterized by a length in any direction less than 500 nm (nanometers), 300 nm, or 200 nm.

21. The method according to claim 20 wherein the pattern of nanostructure features of the given nanostructure layer comprises an optical metasurface of subwavelength antennas.

22. The method according to claim 1 wherein fabricating the given nanostructure layer comprises fabricating on the given nanostructure layer at least one other of the N nanostructure layers on the given nanostructure layer.
